(19) United States
(12) Patent Application Publication
(10) Pub. No.: US 2026/0062285 A1
(43) Pub. Date: Mar. 5, 2026

(54) Transducer

(71) Applicant: SEIKO EPSON CORPORATION, Tokyo (JP)

(72) Inventors: Tomonaga KOBAYASHI, Chino (JP); Teruo TAKIZAWA, Matsumoto (JP)

(21) Appl. No.: 19/314,152

(22) Filed: Aug. 29, 2025

(30) Foreign Application Priority Data
Aug. 30, 2024 (JP) 2024-148499

(51) Int. Cl. B81B 7/00; G01P 15/08; G01P 15/125; G01P 15/18

(52) U.S. Cl. CPC B81B 7/0041; G01P 15/125; G01P 15/18; B81B 2201/0235; B81B 2203/0181; B81B 2203/04; G01P 2015/0848

(57) ABSTRACT

A transducer includes a second semiconductor substrate on which a first insulation layer having a first metal layer on its surface is disposed, a first semiconductor substrate that overlaps the second semiconductor substrate and on which a second insulation layer having a second metal layer on its surface is disposed, a functional element located between the first semiconductor substrate and the second semiconductor substrate, and a eutectic reaction layer bonding the first semiconductor substrate and the second semiconductor substrate to each other in a bonding region located around the functional element. The eutectic reaction layer is a bonding layer formed by eutectic bonding between the first metal layer and the second metal layer. At least one of the first insulation layer and the second insulation layer has a recess having a bottom wider than the bonding region in plan view. The bonding region is located at the bottom.

The present application is based on, and claims priority from JP Application Serial Number 2024-148499, filed Aug. 30, 2024, the disclosure of which is hereby incorporated by reference herein in its entirety.

### BACKGROUND

### 1. Technical Field

The present disclosure relates to a transducer.

### 2. Related Art

A known sensor device traditionally includes a base having a cavity, a sensor element suspended in the cavity, and a lid sealing the cavity. The base and the lid are bonded to each other by a bonding material. The bonding material is required to have high bonding strength and high long-term sealing reliability.

For example, US 2010/0059835 discloses an inertial sensor that uses an AlGe eutectic as a bonding material. According to the document, the Ge concentration in the AlGe eutectic is uniform or is a function of the distance from the lid or base. In particular, the document discloses that a long-time heat treatment makes the Ge concentration uniform.

However, the technique disclosed in US 2010/0059835 may have a problem such as spreading out of the bonding material from the bonding region or scattering of the bonding material, due to the heat treatment for forming the bonding material by the AlGe eutectic. The scattered AlGe eutectic may cause an operation failure of the inertial sensor. The inertial sensor is an example of the transducer, and there is a demand for a highly reliable transducer, which ensures reliable bonding in the bonding region.

### SUMMARY

A transducer includes a first semiconductor substrate having a functional element, a second substrate accommodating the functional element in corporation with the first semiconductor substrate, a first insulation layer on the second semiconductor substrate, a second insulation layer on the first semiconductor substrate, and a eutectic reaction layer bonding the first semiconductor substrate and the second semiconductor substrate to each other in a bonding region. At least one of the first insulation layer and the second insulation layer has a recess having a larger area than the bonding region in plan view.

### BRIEF DESCRIPTION OF THE DRAWINGS

FIG. 1 is a plan view illustrating a schematic structure of a transducer according to a first embodiment.

FIG. 2 is a plan view illustrating a schematic structure of the transducer in FIG. 1 with a second semiconductor substrate serving as a lid being removed.

FIG. 3 is a cross-sectional view taken along line III-III in FIGS. 1 and 2.

FIG. 4 is a cross-sectional view taken along line IV-IV FIGS. 1 and 2.

FIG. 5 is a cross-sectional view illustrating a structure before bonding in FIG. 4.

FIG. 6 is a cross-sectional view taken along line VI-VI in FIGS. 1 and 2.

FIG. 7 is a plan view illustrating a schematic structure of a Y-axis sensor element, which is a functional element illustrated in FIG. 2.

FIG. 8 is a plan view illustrating a schematic structure of a Z-axis sensor element, which is a functional element illustrated in FIG. 2.

FIG. 9 is a plan view illustrating a schematic structure of a transducer according to a second embodiment.

FIG. 10 is a cross-sectional view taken along line X-X in FIG. 9.

FIG. 11 is a cross-sectional view illustrating a structure before bonding in FIG. 10.

FIG. 12 is a plan view illustrating a schematic structure of a transducer according to a third embodiment.

FIG. 13 is a cross-sectional view taken along line XIII-XIII in FIG. 12.

FIG. 14 is a plan view illustrating a schematic structure of a transducer according to a fourth embodiment.

FIG. 15 is a plan view illustrating a schematic structure of the transducer in FIG. 14 with a second semiconductor substrate serving as a lid being removed.

FIG. 16 is a cross-sectional view taken along line XVI-XVI in FIGS. 14 and 15.

FIG. 17 is a cross-sectional view taken along line XVII-XVII in FIGS. 14 and 15.

### DESCRIPTION OF EMBODIMENTS

### 1. First Embodiment

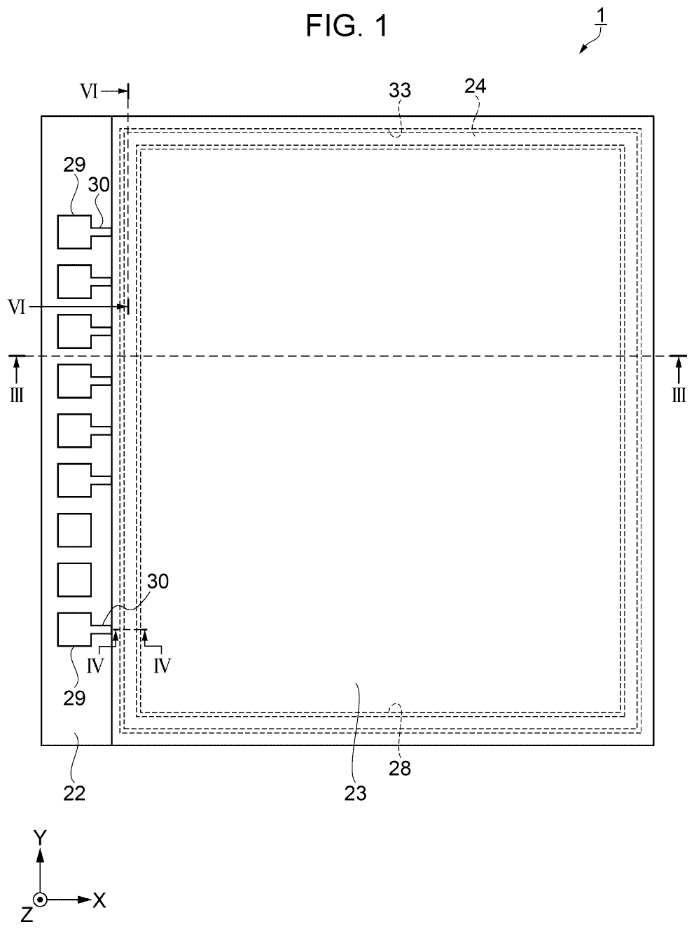

First, as an example of a transducer 1 according to a first embodiment, a 3-axis acceleration sensor that has sensor elements for detecting accelerations in the X, Y, and Z directions as functional elements 2 will be described with reference to FIGS. 1 to 6.

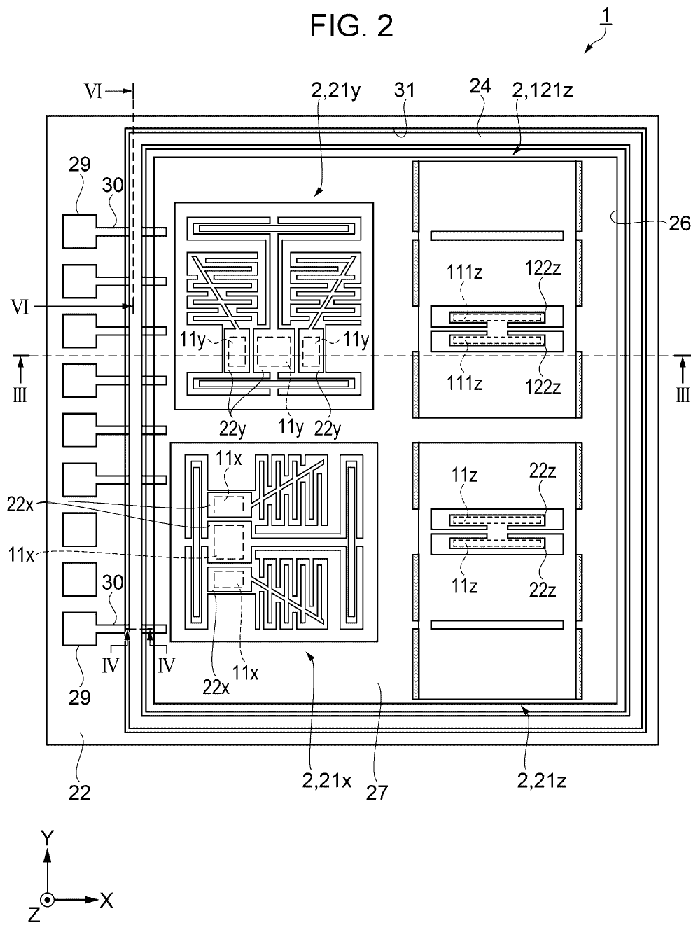

For convenience of description of the internal configuration of the transducer 1, FIG. 2 illustrates a state in which a second semiconductor substrate 23 serving as a lid is removed. FIG. 2 does not illustrate wiring lines each electrically connecting an end of a wiring line 30, which extends in the X direction from a connection terminal 29, to a movable electrode or a fixed electrode of a functional element 2.

Furthermore, for convenience of description, an X axis, a Y axis, and a Z axis are illustrated as three axes orthogonal to each other in each drawing. Furthermore, a direction along the X axis is referred to as an “X direction”, a direction along the Y axis is referred to as a “Y direction”, and a direction along the Z axis is referred to as a “Z direction”. Furthermore, a tip side and a base side of an arrow of each axial direction are referred to as a “positive side” and a “negative side”, respectively. The positive side in the Z direction is referred to as “upper”, and the negative side in the Z direction is referred to as “lower”. The Z direction extends in the vertical direction, and the XY plane extends along the horizontal plane.

In general, a transducer refers to a converter that converts a certain physical quantity into another physical quantity, and examples thereof include an electromechanical transducer, an electroacoustical transducer, and a photoelectric transducer. The transducer according to an aspect of the present application may be any transducer in which a base and a lid are bonded to each other by a eutectic reaction layer. Examples of the transducer include an inertial sensor that converts an acceleration or angular velocity into an electric signal, a vibrator (timing device) in which mechanical vibration is excited by an electric signal, an ultrasonic sensor that converts an ultrasonic signal into an electric signal, an RF filter using an electromechanical coupling coefficient of a piezoelectric material, a piezoelectric mirror, a piezoelectric actuator, and a pressure sensor.

In the embodiment, a 3-axis acceleration sensor, which is one of inertial sensors, will be described as an example of the transducer. In an acceleration sensor in which a MEMS device element in a base is sealed with a lid, upon application of an acceleration as an external force, an inertial force acts in the MEMS device element, and a capacitance value in the element changes. The change in the capacitance is converted into an electric signal by using a differential detection circuit or the like and is taken out as a sensor signal.

In the present embodiment, the functional elements 2 are three sensor elements constituting a 3-axis acceleration sensor, but may be a sensor element constituting a uniaxial acceleration sensor, another sensor element, a vibrating element constituting a vibrator, or a piezoelectric mirror element constituting a piezoelectric mirror.

The transducer 1 illustrated in FIGS. 1 to 6 can be used as a 3-axis acceleration sensor capable of independently detecting accelerations in three directions. As illustrated in FIGS. 1, 2, 3, 4, and 6, the transducer 1 includes a first semiconductor substrate 22 having a functional element 2, a second semiconductor substrate 23 accommodating the functional element 2 in corporation with the first semiconductor substrate 22, a first insulation layer 34 on the second semiconductor substrate 23, a second insulation layer 32 on the first semiconductor substrate 22, and a eutectic reaction layer 24 bonding the first semiconductor substrate 22 and the second semiconductor substrate 23 to each other in a bonding region 35.

As illustrated in FIGS. 1, 2, and 3, the first semiconductor substrate 22, which corresponds to a base, has a recess 26 recessed from the upper surface in an opposite direction from the second semiconductor substrate 23 and has multiple support portions 11x, 11y, 11z, and 111z protruding upward from an inner bottom surface 27 of the recess 26. Sensor elements 21x, 21y, 21z, and 121z for detecting accelerations in the X, Y, and Z directions, which are the functional elements 2, are fixed to the upper surfaces of the support portions 11x, 11y, 11z, and 111z so as to be accommodated in the recess 26 in plan view. This embodiment, which includes the sensor elements 21z and 121z for detecting two accelerations in the Z direction, can detect the acceleration in the Z direction with higher accuracy.

The X sensor element 21x for detecting an acceleration in the X direction has a fixed portion 22x, and the fixed portion 22x is fixed to the upper surface of the support portion 11x. The Y-axis sensor element 21y for detecting an acceleration in the Y direction has a fixed portion 22y, and the fixed portion 22y is fixed to the upper surface of the support portion 11y. The Z-axis sensor element 21z for detecting an acceleration in the Z direction has a fixed portion 22z, and the fixed portion 22z is fixed to the upper surface of the support portion 11z. The Z-axis sensor element 121z for detecting an acceleration in the Z direction has a fixed portion 122z, and the fixed portion 122z is fixed to the upper surface of the support portion 111z.

As illustrated in FIGS. 4 and 6, a second insulation layer 32 is on the first semiconductor substrate 22, and the second insulation layer 32 has a recess 31 surrounding the recess 26 and recessed from the upper surface in the opposite direction from the second semiconductor substrate 23 in plan view. An insulation layer 20 for preventing conduction between the wiring line 30 and the first semiconductor substrate 22 is on the first semiconductor substrate 22.

Furthermore, multiple connection terminals 29 are arranged in the Y direction on an end in the negative X direction of the first semiconductor substrate 22 at positions not overlapping the second semiconductor substrate 23 in plan view. The wiring line 30 extends in the X direction from each of the connection terminals 29. The second insulation layer 32 is not present on the connection terminals 29 and the wiring lines 30, which are located at the positions not overlapping the second semiconductor substrate 23 in plan view.

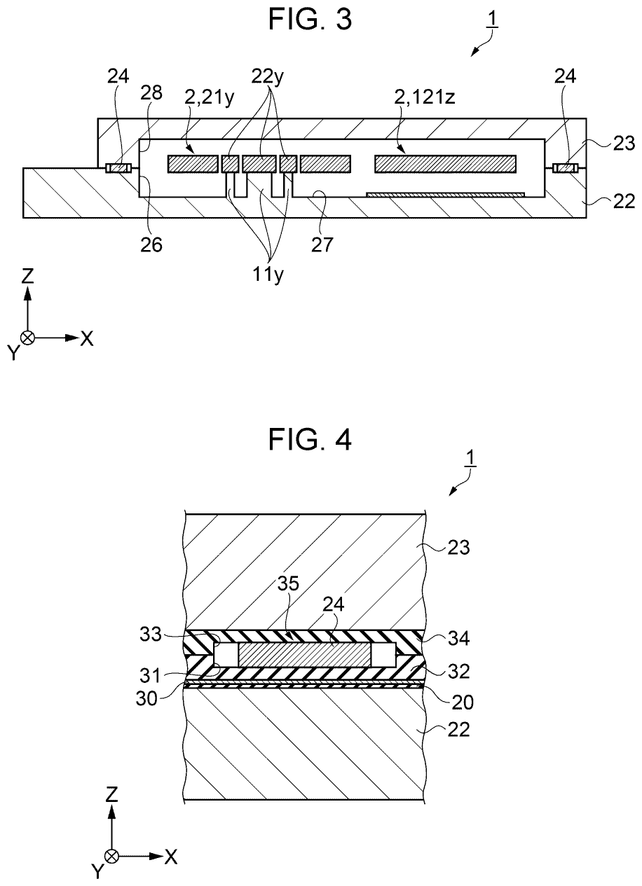

The second semiconductor substrate 23, which corresponds to a lid, has a recess 28 recessed from the lower surface in the opposite direction from the first semiconductor substrate 22 as illustrated in FIGS. 1 and 3, and the recess 28 accommodates the functional elements 2 in corporation with the recess 26 in the first semiconductor substrate 22.

As illustrated in FIGS. 4 and 6, a first insulation layer 34 is on the lower surface of the second semiconductor substrate 23, and the first insulation layer 34 has a recess 33 surrounding the recess 28 and recessed from the lower surface in the opposite direction from the first semiconductor substrate 22 in plan view. The recess 33 in the first insulation layer 34 is located at a position overlapping the recess 31 in the second insulation layer 32 in plan view.

The first semiconductor substrate 22 and the second semiconductor substrate 23 are bonded to each other by the eutectic reaction layer 24 in a bonding region 35 between the recess 31 in the second insulation layer 32 of the first semiconductor substrate 22 and the recess 33 in the first insulation layer 34 of the second semiconductor substrate 23. The recess 31 in the second insulation layer 32 and the recess 33 in the first insulation layer 34 have a larger area than the bonding region 35 in plan view. In other words, the length in the X direction of the eutectic reaction layer 24 defining the bonding region 35 is shorter than the length in the X direction of the recesses 31 and 33, and the length in the Y direction of the eutectic reaction layer 24 defining the bonding region 35 is shorter than the length in the Y direction of the recesses 31 and 33. This can prevent the bonding region 35 of the eutectic reaction layer 24 as the bonding material from spreading out of the recesses 31 and 33 and can prevent the eutectic reaction layer 24 as the bonding material from scattering.

In the present embodiment, the first insulation layer 34 and the second insulation layer 32 have the recess 31 and 33 having a larger area than the bonding region 35 in plan view, but this should not be construed as limiting. Only one of the first insulation layer 34 and the second insulation layer 32 may have the recess 31 or 33, which has a larger area than the bonding region 35 in plan view.

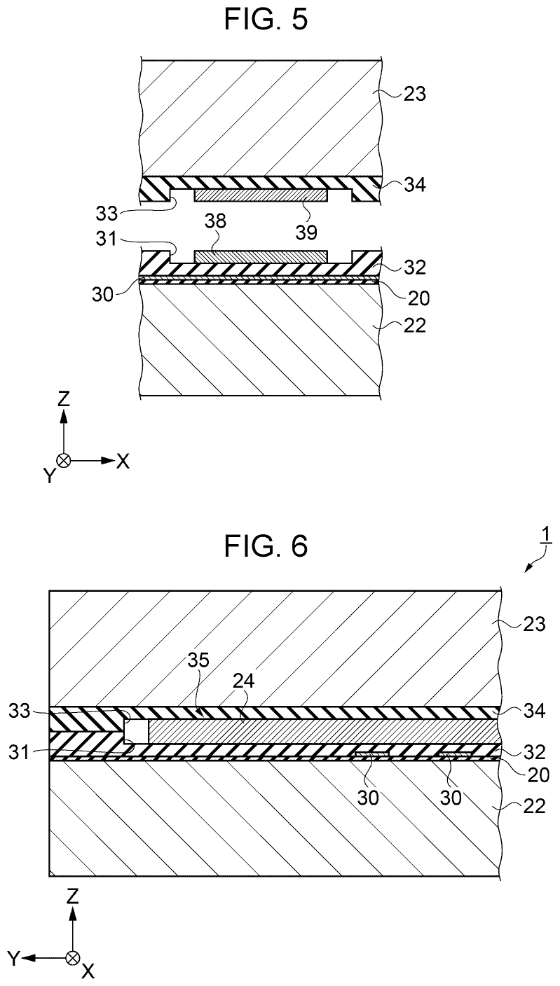

FIG. 5 is a cross-sectional view of main components of the first semiconductor substrate 22 and the second semiconductor substrate 23 before bonding and corresponds to FIG. 4. Before the bonding, as illustrated in FIG. 5, a first metal layer 39 is provided in the recess 33 in the first insulation layer 34, and a second metal layer 38 is provided in the recess 31 in the second insulation layer 32.

The first metal layer 39 is a Ge layer. The second metal layer 38 is an AlCu layer. The AlCu layer contains Cu for the purpose of preventing electromigration, and the content thereof is low. Thus, the main component of the second metal layer 38 is Al.

The first metal layer 39 and the second metal layer 38 are bonded to each other by a heating process and a weighting process. More specifically, the stack including the first semiconductor substrate 22 and the second semiconductor substrate 23 is heated to a temperature equal to or higher than the eutectic temperature between the first metal layer 39 and the second metal layer 38 and is further weighted while being heated to be subjected to eutectic bonding. The eutectic temperature of AlGe is about 420° C. In a preferred example, the stack is set on a stage of a heating jig with the first semiconductor substrate 22 being located below the second semiconductor substrate 23, and when the stack reaches a predetermined temperature, a load is applied from the second semiconductor substrate 23 side by a weighting jig for a predetermined time. At this time, the weighting jig is also heated. The eutectic generally refers to an alloy formed by solidification of two or more kinds of mixed metals in a liquid phase state.

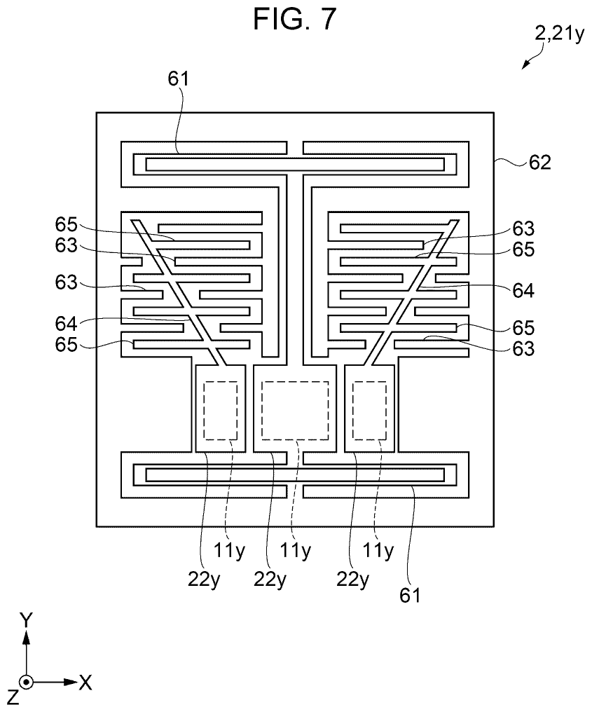

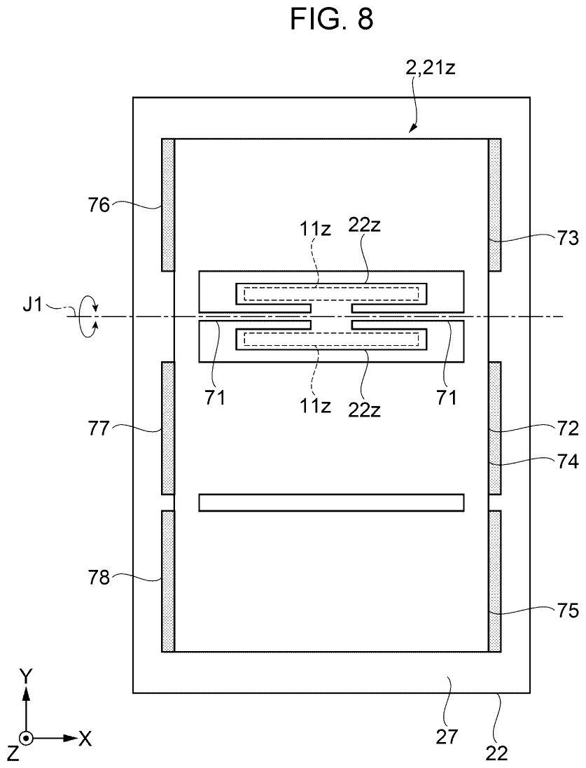

Next, the principle of how the Y-axis sensor element 21y, the X-axis sensor element 21x, and the Z-axis sensor elements 21z and 121z, which are the functional elements 2, detect accelerations will be described with reference to FIGS. 7 and 8.

As illustrated in FIG. 7, the Y-axis sensor element 21y includes three fixed portions 22y arranged in the X direction and two coupling portions 61 arranged in the Y direction. The three fixed portions 22y are located between the two coupling portions 61. The fixed portion 22y in the middle and the coupling portions 61 are coupled. Furthermore, the distance between the coupling portion 61 located on the positive Y direction side and the fixed portions 22y is longer than the distance between the coupling portion 61 located on the negative Y direction side and the fixed portions 22y.

The two coupling portions 61 are coupled to a movable portion 62, which surrounds the two coupling portions 61 and the three fixed portions 22y, on the opposite side from the fixed portions 22y. The movable portion 62 includes multiple movable electrodes 63 extending in the positive X direction and the negative X direction and located between the coupling portion 61 on the positive Y direction side and the fixed portions 22y. The coupling portion 61 can be elastically deformed in the Y direction like a spring, enabling the movable portion 62 to be displaced in the Y direction.

The two fixed portions 22y located on the positive and negative X direction sides of the middle fixed portion 22y each include a fixed beam 64 extending obliquely in the Y direction and the multiple fixed electrodes 65 extending from the fixed beam 64 in the positive and negative X directions. The fixed electrodes 65 are positioned on the positive and negative Y direction sides of the movable electrodes 63 and are arranged in a comb-tooth shape so as to mesh with the corresponding movable electrodes 63 with a space therebetween.

When such a Y-axis sensor element 21y is subjected to an acceleration in the Y direction, the movable portion 62 is displaced in the Y direction depending on the magnitude of the acceleration. Since the capacitance between the movable electrode 63 and the fixed electrode 65 changes depending on the displacement, the acceleration can be determined based on the change in the capacitance.

The X-axis sensor element 21x is an element that detects an acceleration in the X direction. The X-axis sensor element 21x has the same configuration as the Y-axis sensor element 21y except that the X-axis sensor element 21x is turned 90 degrees in plan view with respect to the Y-axis sensor element 21y.

The coupling portion 61 coupled to the fixed portions 22x can be elastically deformed in the X direction like a spring, enabling the movable portion 62 to be displaced in the X direction. Thus, the acceleration in the X direction can be detected.

As illustrated in FIG. 8, the Z-axis sensor element 21z includes fixed portions 22z, a movable portion 72, and a pair of support beams 71 that couple the movable portion 72 to the fixed portions 22z in a swingable manner. The movable portion 72 swings like a seesaw with respect to the fixed portions 22z using the support beams 71 as a shaft J1. Such a Z-axis sensor element 21z is formed of, for example, a silicon substrate doped with impurities such as phosphorus and boron.

The fixed portions 22z are anodically bonded to the upper surface of the support portions 11z protruding upward from the inner bottom surface 27 of the recess 26 in the first semiconductor substrate 22. The movable portion 72 is on the positive and negative Y direction sides of the fixed portions 22z. The movable portion 72 includes a first movable electrode 73 located on the positive Y direction side of the shaft J1 and second and third movable electrodes 74 and 75 located on the negative Y direction side of the shaft J1. The first movable electrode 73 and the second movable electrode 74 have different rotation moments when an acceleration in the Z direction is applied and are designed such that the movable portion 72 is tilted by a predetermined degree depending on the acceleration. Accordingly, when an acceleration in the Z-direction is caused, the movable portion 72 swings like a seesaw about the shaft J1.

In addition, on the inner bottom surface 27 of the recess 26, a first detection electrode 76 is disposed at a position opposed to the first movable electrode 73, a second detection electrode 77 is disposed at a position opposed to the second movable electrode 74, and a dummy electrode 78 is disposed at a position opposed to the third movable electrode 75. Thus, an electrostatic capacitance is formed between the first movable electrode 73 and the first detection electrode 76, and an electrostatic capacitance is formed between the second movable electrode 74 and the second detection electrode 77. The dummy electrode 78 is provided to reduce charging on the inner bottom surface 27 of the recess 26.

When such a Z-axis sensor element 21z is subjected to an acceleration in the Z direction, the movable portion 72 swings like a seesaw about the shaft J1. The seesaw-like swinging of the movable portion 72 changes the separation distance between the first movable electrode 73 and the first detection electrode 76 and the separation distance between the second movable electrode 74 and the second detection electrode 77, resulting in changes in the capacitance between them. Thus, the acceleration can be determined based on the change in the capacitance.

The Z-axis sensor element 121z is an element that detects an acceleration in the Z direction. The Z-axis sensor element 121z has the same configuration as the Z-axis sensor element 21z except that the Z-axis sensor element 121z is turned 180 degrees in plan view with respect to the Z-axis sensor element 21z.

In this embodiment, the transducer 1 in which the functional element 2 is bonded to the first semiconductor substrate 22 has been described as an example, but this should not be construed as limiting. The first semiconductor substrate 22 may be a silicon on insulator (SOI) substrate and may integrally include the functional element 2.

As described above, in the transducer 1 of the present embodiment, the recess 31 in the second insulation layer 32 and the recess 33 in the first insulation layer 34 have a larger area than the bonding region 35 defined by the eutectic reaction layer 24 in plan view. This can prevent the bonding region 35 of the eutectic reaction layer 24, which is the bonding material, from spreading out of the recesses 31 and 33 and can prevent the eutectic reaction layer 24 as the bonding material from scattering.

### 2. Second Embodiment

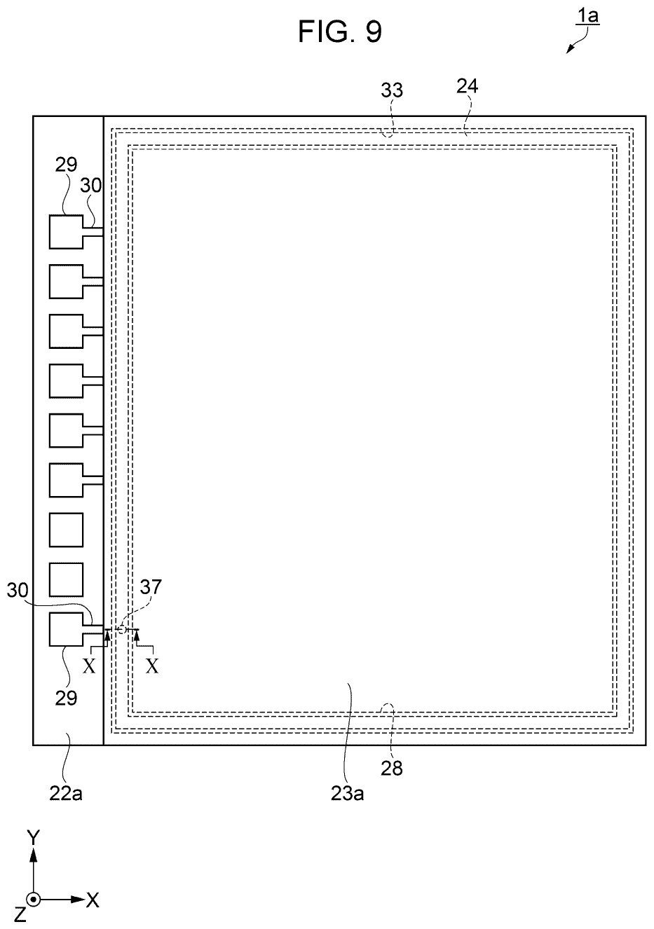

Next, a transducer 1a according to a second embodiment will be described with reference to FIGS. 9, 10, and 11.

The transducer 1a of this embodiment is the same as the transducer 1 of the first embodiment except that a first insulation layer 34a and a second insulation layer 32a have a different configuration from those of the transducer 1 of the first embodiment. Differences from the first embodiment described above will be mainly described, and similarities will not be described.

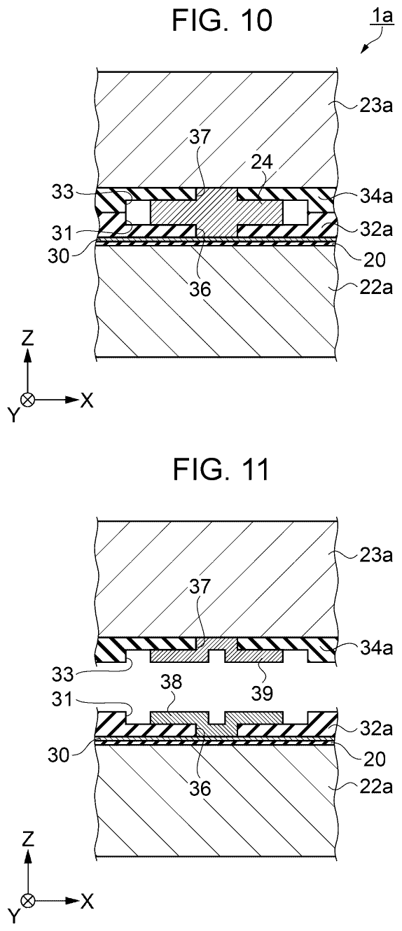

As illustrated in FIGS. 9 and 10, the transducer 1a includes a first semiconductor substrate 22a having the functional element 2, a second semiconductor substrate 23a accommodating the functional element 2 in corporation with the first semiconductor substrate 22a, a first insulation layer 34a on the second semiconductor substrate 23a, a second insulation layer 32a on the first semiconductor substrate 22a, and a eutectic reaction layer 24 bonding the first semiconductor substrate 22a and the second semiconductor substrate 23a to each other in the bonding region 35. An insulation layer 20 for preventing conduction between the wiring line 30 and the first semiconductor substrate 22a is on the first semiconductor substrate 22a.

The first insulation layer 34a has a first through hole 37 in a region overlapping the eutectic reaction layer 24 and the recess 33 in plan view. The second semiconductor substrate 23a and the eutectic reaction layer 24 are in contact with each other through the first through hole 37. Thus, the second semiconductor substrate 23a and the eutectic reaction layer 24 can have the same potential.

The second insulation layer 32a has a second through hole 36 at a position overlapping the first through hole 37 in a region overlapping the eutectic reaction layer 24 and the recess 31 in plan view. The wiring line 30 located between the first semiconductor substrate 22a and the second insulation layer 32a is in contact with the eutectic reaction layer 24 through the second through hole 36. Thus, the wiring line 30 and the eutectic reaction layer 24 can have the same potential.

Before the bonding, as illustrated in FIG. 11, the second semiconductor substrate 23a and the first metal layer 39 are in contact with each other through the first through hole 37 in the first insulation layer 34a, and the wiring line 30 and the second metal layer 38 are in contact with each other through the second through hole 36 in the second insulation layer 32a.

With such a configuration, the eutectic reaction layer 24, the second semiconductor substrate 23a, and the wiring line 30 can have the same potential, and thus the transducer 1a can provide the same effects as the transducer 1 of the first embodiment.

### 3. Third Embodiment

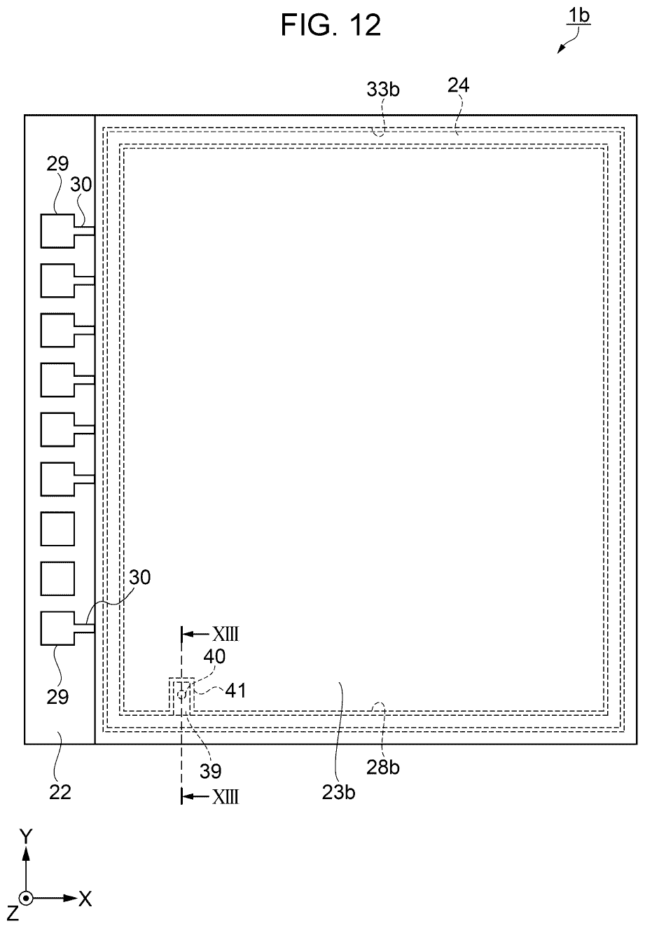

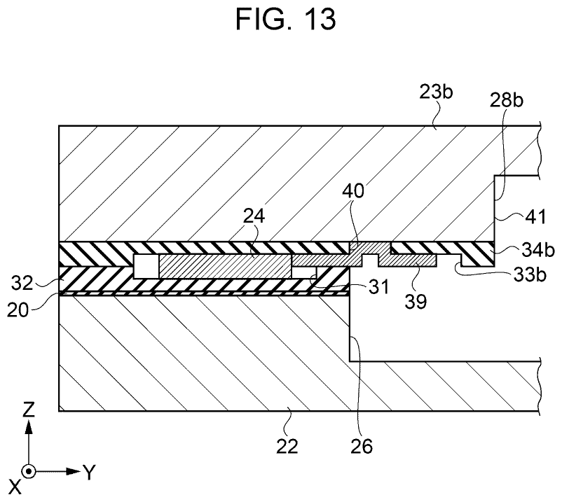

Next, a transducer 1b according to a third embodiment will be described with reference to FIGS. 12 and 13.

The transducer 1b of this embodiment is the same as the transducer 1 of the first embodiment except that a recess 33b in a first insulation layer 34b has a different configuration from that of the transducer 1 of the first embodiment. Differences from the first embodiment described above will be mainly described, and similarities will not be described.

As illustrated in FIGS. 12 and 13, the transducer 1b includes the first semiconductor substrate 22 having the functional element 2, a second semiconductor substrate 23b accommodating the functional element 2 in corporation with the first semiconductor substrate 22, the first insulation layer 34b on the second semiconductor substrate 23b, the second insulation layer 32 on the first semiconductor substrate 22, and the eutectic reaction layer 24 bonding the first semiconductor substrate 22 and the second semiconductor substrate 23b to each other in the bonding region 35. An insulation layer 20 for preventing conduction between the wiring line 30 and the first semiconductor substrate 22 is on the first semiconductor substrate 22.

The second semiconductor substrate 23b has a recess 28b having a protrusion 41 extending from a Y direction side end in the positive Y direction.

The recess 33b in the first insulation layer 34b on the lower surface of the second semiconductor substrate 23b has a third through hole 40 at the protrusion 41, and the second semiconductor substrate 23b is in contact with the non-eutectic first metal layer 39 through the third through hole 40. Thus, the second semiconductor substrate 23b and the eutectic reaction layer 24 are in contact with each other through the first metal layer 39, and the second semiconductor substrate 23b and the eutectic reaction layer 24 can have the same potential.

With such a configuration, the eutectic reaction layer 24 and the second semiconductor substrate 23b can have the same potential, and thus the transducer 1b can provide the same effects as the transducer 1 of the first embodiment.

### 4. Fourth Embodiment

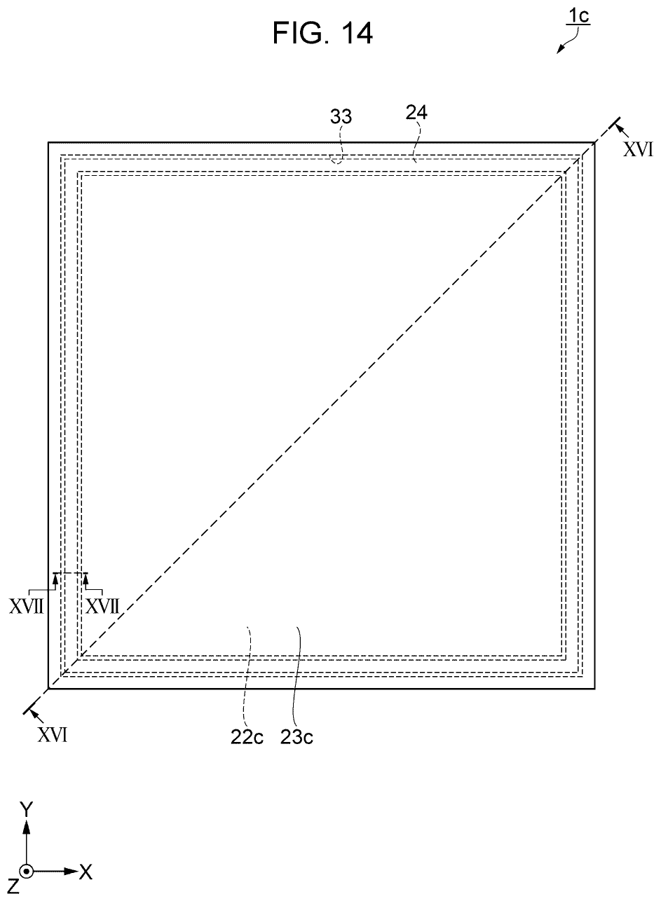

Next, a transducer 1c according to a fourth embodiment will be described with reference to FIGS. 14 to 17.

The transducer 1c of this embodiment is the same as the transducer 1 of the first embodiment except that a functional element 2c has a different configuration from that of the transducer 1 of the first embodiment. Differences from the first embodiment described above will be mainly described, and similarities will not be described.

As illustrated in FIGS. 14 to 17, the transducer 1c is a vibrator having a three legged structure and includes a first semiconductor substrate 22c having a functional element 2c, a second semiconductor substrate 23c accommodating the functional element 2c in corporation with the first semiconductor substrate 22c, the first insulation layer 34 on the second semiconductor substrate 23c, the second insulation layer 32 on the first semiconductor substrate 22c, and the eutectic reaction layer 24 bonding the first semiconductor substrate 22c and the second semiconductor substrate 23c to each other in the bonding region 35.

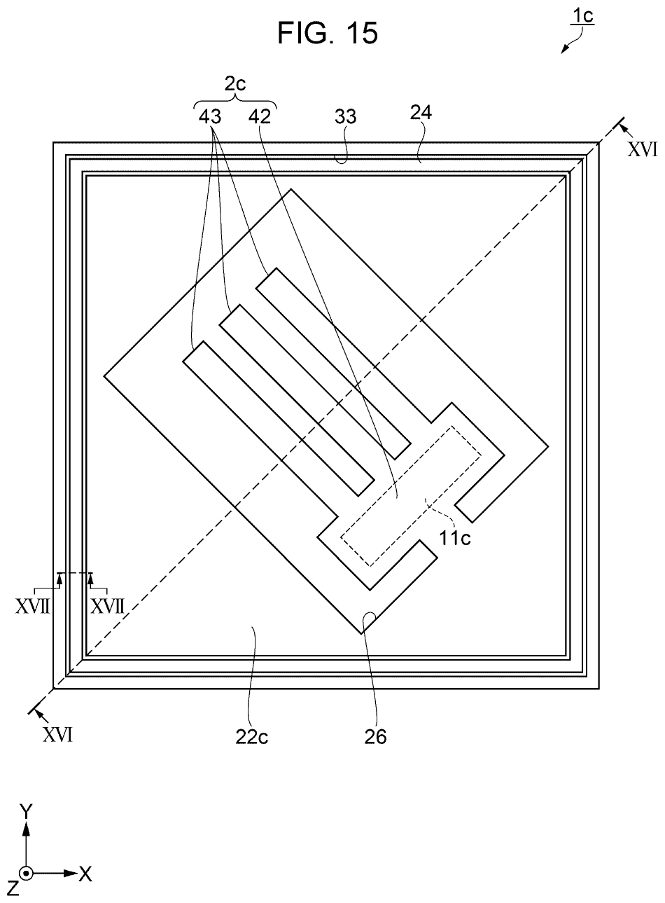

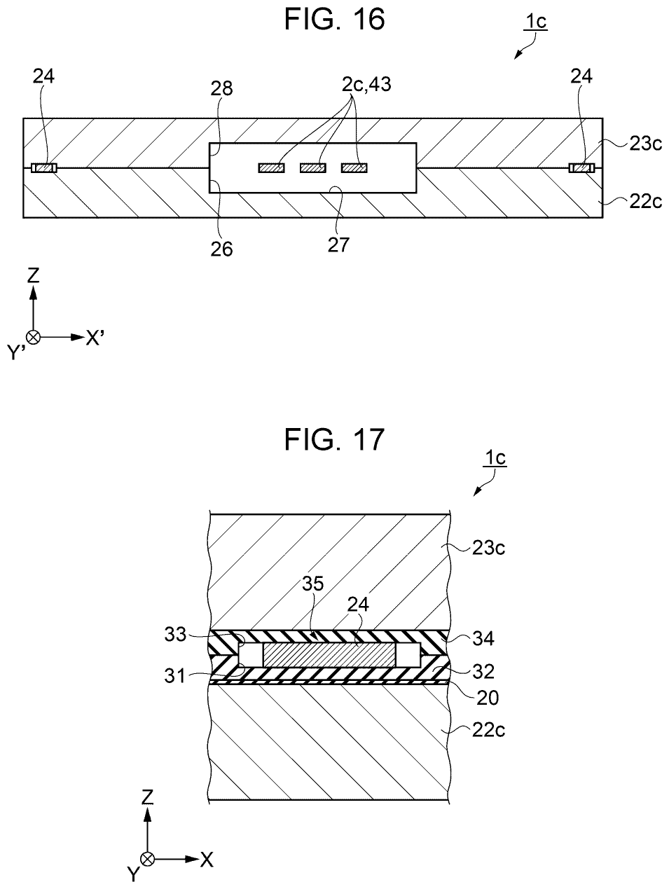

As illustrated in FIGS. 15 and 16, the first semiconductor substrate 22c has the recess 26 recessed from the upper surface in the opposite direction from the second semiconductor substrate 23c and has a support portion 11c protruding upward from an inner bottom surface 27 of the recess 26. On the upper surface of the support portion 11c, a vibrating device having three vibrating arms 43, which is the functional element 2c, is fixed so as to be accommodated in the recess 26 in plan view.

The functional element 2c has a fixed portion 42 and three vibrating arms 43 extending in a predetermined direction from the fixed portion 42. The fixed portion 42 is fixed to the upper surface of the support portion 11c.

As illustrated in FIG. 17, the second insulation layer 32 is on the first semiconductor substrate 22c, and the second insulation layer 32 has the recess 31 surrounding the recess 26 and recessed from the upper surface in the opposite direction from the second semiconductor substrate 23 in plan view. The insulation layer 20 for preventing conduction between a wiring line (not illustrated) and the first semiconductor substrate 22c is on the first semiconductor substrate 22c.

As illustrated in FIG. 16, the second semiconductor substrate 23c has the recess 28 recessed from the lower surface in the opposite direction from the first semiconductor substrate 22c and accommodates the functional element 2c in corporation with the recess 26 in the first semiconductor substrate 22c.

The first insulation layer 34 is on the lower surface of the second semiconductor substrate 23c, and the first insulation layer 34 has the recess 33 surrounding the recess 28 and recessed from the lower surface in the opposite direction from the first semiconductor substrate 22c in plan view. The recess 33 in the first insulation layer 34 is located at a position overlapping the recess 31 in the second insulation layer 32 in plan view.

The first semiconductor substrate 22c and the second semiconductor substrate 23c are bonded to each other by the eutectic reaction layer 24 in the bonding region 35 between the recess 31 in the second insulation layer 32 of the first semiconductor substrate 22c and the recess 33 in the first insulation layer 34 of the second semiconductor substrate 23c. The recess 31 in the second insulation layer 32 and the recess 33 in the first insulation layer 34 have a larger area than the bonding region 35 in plan view.

With this configuration, the transducer 1c can provide the same effects as the transducer 1 of the first embodiment.

What is claimed is:

1. A transducer comprising:
when three axes orthogonal to each other are defined as an X axis, a Y axis, and a Z axis,
a second semiconductor substrate on which a first insulation layer having a first metal layer on its surface is disposed;
a first semiconductor substrate that overlaps the second semiconductor substrate in a Z direction extending along the Z axis and on which a second insulation layer having a second metal layer on its surface is disposed;
a functional element located between the first semiconductor substrate and the second semiconductor substrate; and
a eutectic reaction layer bonding the first semiconductor substrate and the second semiconductor substrate to each other in a bonding region located around the functional element, wherein
the eutectic reaction layer is a bonding layer formed by eutectic bonding between the first metal layer and the second metal layer,
at least one of the first insulation layer and the second insulation layer includes a recess having a bottom wider than the bonding region in plan view in the Z direction, and
the bonding region is located at the bottom.

2. The transducer according to claim 1, wherein the first insulation layer has a first through hole in a region overlapping the eutectic reaction layer and the recess in plan view in the Z direction, and
the eutectic reaction layer fills the first through hole and is bonded to the second semiconductor substrate.

3. The transducer according to claim 2, further comprising a wiring line between the first semiconductor substrate and the second insulation layer, wherein
the second insulation layer has a second through hole in a region overlapping the eutectic reaction layer and the recess in plan view in the Z direction, and
the eutectic reaction layer fills the second through hole and is bonded to the wiring line.

4. The transducer according to claim 3, wherein the first through hole and the second through hole overlap each other in plan view in the Z direction.

5. The transducer according to claim 1, wherein the first metal layer is a Ge layer, and the second metal layer is a layer containing Al as a main component.

6. The transducer according to claim 5, wherein the second metal layer is an AlCu layer.
